(19) United States
(12) Patent Application Publication
(10) Pub. No.: US 2026/0259161 A1
(43) Pub. Date: Sep. 3, 2026

(54) MEASUREMENT CELL AND CONNECTION DEVICE

(71) Applicant: HIOKI E.E. CORPORATION, Nagano (JP)

(72) Inventors: Akihiro SHIOIRI, Nagano (JP); Naoto NAKAYAMA, Nagano (JP); Tetsuya YOSHIIKE, Nagano (JP); Manabu YAMANOUCHI, Nagano (JP); Takahiro SANO, Nagano (JP)

(21) Appl. No.: 18/846,818

(22) PCT Filed: Mar. 14, 2023
(86) PCT No.: PCT/JP2023/009927

§ 371 Date: Sep. 13, 2024

(30) Foreign Application Priority Data
Mar. 14, 2022 (JP) 2022-039339
Mar. 14, 2022 (JP) 2022-039340

(51) Int. Cl. G01N 27/07; G01N 27/22; G01N 27/74

(52) U.S. Cl. CPC G01N 27/07; G01N 27/226; G01N 27/74

(57) ABSTRACT

Provided is a measurement cell capable of improving measurement accuracy of electrical characteristics of a liquid. A measurement cell for measuring electrical characteristics of a liquid includes a containing portion configured to contain a liquid and a pair of electrode portions attached to the container portion. The pair of electrode portions each include an inner electrode provided inside the container portion and an outer electrode provided outside the container portion, the inner electrodes of the pair of electrode portions facing each other.

### TECHNICAL FIELD

The present invention relates to a measurement cell and connection device.

### BACKGROUND ART

In known art, a chip component jig for four-terminal measurement is proposed that is to be used for a lower surface electrode type chip component (see Patent Document 1, for example). With the jig described in Patent Document 1, two terminal blocks each have a contact terminal, and the two terminal blocks can be brought into contact with and separated from each other, so that the jig can cope with chip components of different sizes.

### CITATION LIST

### Patent Literature

Patent Document 1: JP 2008-26260 A

### SUMMARY OF INVENTION

### Technical Problem

When electrical characteristics of a target object are measured by a four-terminal measurement method or the like, the target object may be a liquid. In such a case, it is possible to measure electrical characteristics, such as impedance, of the liquid by containing the liquid in a container such as a beaker, for example, and disposing a pair of counter electrodes are inside the container. However, it is necessary to clean the container and the electrodes after one measurement is completed, and it is necessary to dispose the electrodes again at the time of the next measurement. At this time, there is a possibility that an interval between the counter electrodes or the like may change for each measurement, and there is a disadvantage that the accuracy of the measurement easily deteriorates.

The present invention has been made in view of the above-described problem, and an object of the present invention is to provide a measurement cell capable of improving measurement accuracy of electrical characteristics of a liquid.

### Solution to Problem

A measurement cell according to a typical embodiment of the present invention is a measurement cell for measuring electrical characteristics of a liquid. The measurement cell includes a containing portion configured to contain a liquid and a pair of electrode portions attached to the containing portion. The pair of electrode portions each include an inner electrode provided inside the containing portion and an outer electrode provided outside the containing portion, the inner electrodes of the pair of electrode portions facing each other.

### Advantageous Effects of Invention

According to the measurement cell according to the present invention, it is possible to improve measurement accuracy of electrical characteristics of a liquid.

### BRIEF DESCRIPTION OF DRAWINGS

FIG. 1 is a perspective view illustrating a measurement unit including a connection device according to an embodiment.

FIG. 2 is a perspective view illustrating a measurement cell of the measurement unit including the connection device according to the embodiment.

FIG. 3 is a front view illustrating the measurement cell of the measurement unit including the connection device according to the embodiment.

FIG. 4 is a rear view illustrating the measurement cell of the measurement unit including the connection device according to the embodiment.

FIG. 5 is a right side view illustrating the measurement cell of the measurement unit including the connection device according to the embodiment.

FIG. 6 is a left side view illustrating the measurement cell of the measurement unit including the connection device according to the embodiment.

FIG. 7 is a plan view illustrating the measurement cell of the measurement unit including the connection device according to the embodiment.

FIG. 8 is a bottom view illustrating the measurement cell of the measurement unit including the connection device according to the embodiment.

FIG. 9 is a cross-sectional view illustrating the measurement cell of the measurement unit including the connection device according to the embodiment.

FIG. 10 is a perspective view illustrating the connection device according to the embodiment.

FIG. 11 is a front view illustrating the connection device according to the embodiment.

FIG. 12 is a rear view illustrating the connection device according to the embodiment.

FIG. 13 is a plan view illustrating the connection device according to the embodiment.

FIG. 14 is a perspective view illustrating a part of the connection device according to the embodiment.

FIG. 15 is a front view schematically illustrating a measurement unit according to a modified example.

### DESCRIPTION OF EMBODIMENTS

### 1. Overview of Embodiments

First, an overview of typical embodiments of the invention disclosed in the present application will be described. Note that, in the following description, reference signs in the drawings corresponding to structural elements of the invention are shown in parentheses, for example.
[1] A measurement cell (1) according to a typical embodiment of the present invention is a measurement cell for measuring electrical characteristics of a liquid. The measurement cell (1) includes a containing portion (2) configured to contain a liquid and a pair of electrode portions (3) attached to the containing portion (2). The pair of electrode portions (3) each include an inner electrode (31) provided inside the containing portion (2) and an outer electrode (32) provided outside the containing portion (2), the inner electrodes (31) of the pair of electrode portions (3) facing each other.
[2] In the measurement cell (1) according to [1] described above, the containing portion (2) may include a tube-like portion (21)whose one end opens and a protruding portion (22) that is continuous with the other end of the tube-like portion (21) and has an outer diameter decreasing toward a tip end. The tube-like portion (21) may include a boundary portion with the protruding portion (22), include a bottom portion (212) at a position on a side of the one end and may be capable of containing the liquid.
[3] In the measurement cell (1) according to [1] or [2] described above, the electrode portion (3) may be a rod-shaped member penetrating the containing portion (2).
[4] In the measurement cell (1) according to [3] described above, the containing portion (2) may include a tubular attachment portion (23) that protrudes outward, the electrode portion (3) being inserted through the tubular attachment portion (23).
[5] In the measurement cell (1) according to [4] described above, the containing portion (2) may include a reinforcing portion (24) extending between a pair of the tubular attachment portions (23).
[6] In the measurement cell (1) according to any one of [1] to [5] described above, the containing portion (2) may be made of a translucent member and may include a reference line (214) closer to an inlet side than the inner electrode (31).
[7] A connection device (10) according to a typical embodiment of the present invention includes a housing recess (43) configured to house a measurement cell (1) including a tube-like portion, a terminal portion (5) to be connected to a measurement device for measuring electrical characteristics of a liquid contained in the measurement cell (1), a pair of contact portions (61) configured to contact a pair of respective electrode portions (3) provided in the measurement cell (1), and a connection portion (62) configured to electrically connect the terminal portion (5) and the contact portion (61). The contact portions (61) are disposed at positions contacting the respective electrode portions (3) when the measurement cell (1) is housed to a predetermined housing depth in the housing recess (43).
[8] The connection device (10) according to [7] may include a casing portion (4) in which the housing recess (43) is formed. The casing portion (4) may include a metal shield portion (41) at least at positions at which the pair of contact portions (61) are sandwiched from an opposing direction (X2 direction) in which the pair of contact portions (61) face each other.
[9] In the connection device (10) according to [8] described above, the casing portion (4) may include an insulator portion (42) in which the housing recess (43) is formed. The shield portion (41) may be formed in a box shape and include an opening portion (416) in which the insulator portion (42) is housed, a pair of opposing plate portions (412. 413) facing each other in the opposing direction, and a pair of connection plate portions (414, 415) connecting the pair of opposing plate portions (412. 413) to each other. At an end edge on a side of the opening portion (416) of each of the connection plate portions (414, 415), a cutout portion (417) may be formed at a position at which the contact portions (61) are sandwiched.

### 2. Specific Examples of Embodiments

Hereinafter, specific examples of the embodiments of the present invention will be described with reference to the drawings. Note that, in the following description, the same reference signs are assigned to structural elements that are common to each of the embodiments, and a repeated description thereof will be omitted.

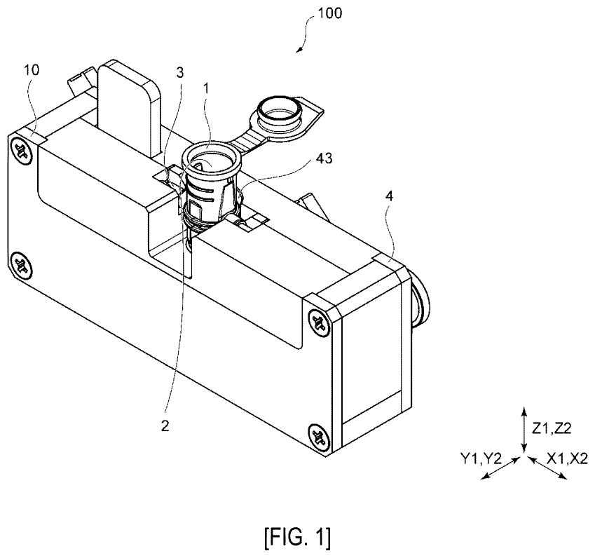

FIG. 1 is a perspective view illustrating a measurement unit 100 including a measurement cell 1 according to a present embodiment. The measurement unit 100 includes the measurement cell 1 and a connection device 10. As a result of being connected to an LCR meter or the like that is a measurement device, for example, the measurement unit 100 is a unit for measuring the impedance of slurry that is a liquid contained in the measurement cell 1. Note that the liquid to be measured is not limited to the slurry, and may be a plating liquid or the like. The electrical characteristics to be measured is not limited to the impedance and may be series resistance, reactance or the like. Hereinafter, the measurement cell 1 and the connection device 10 will be individually described, and subsequently, a mutual positional relationship and the like will be described.

### [Measurement Cell]

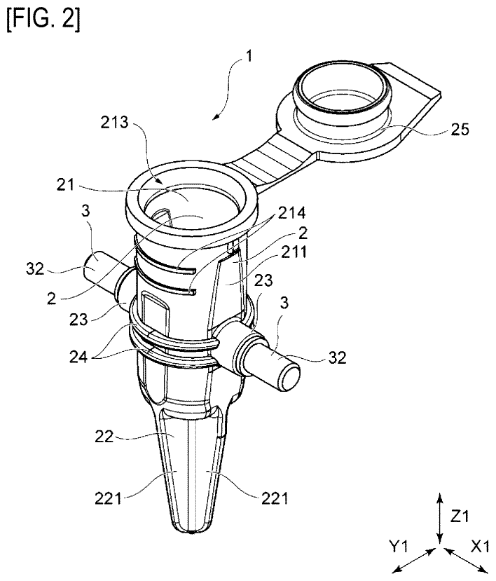

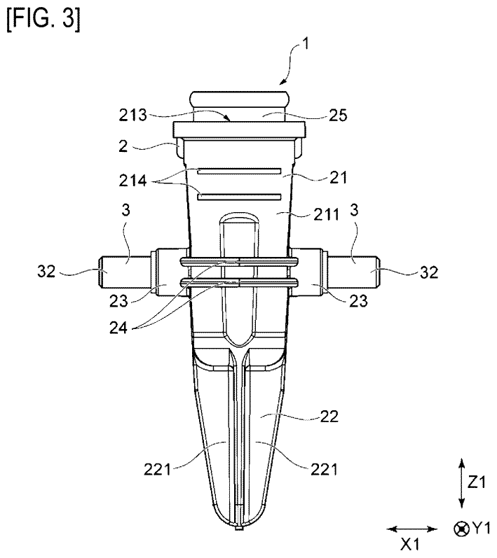

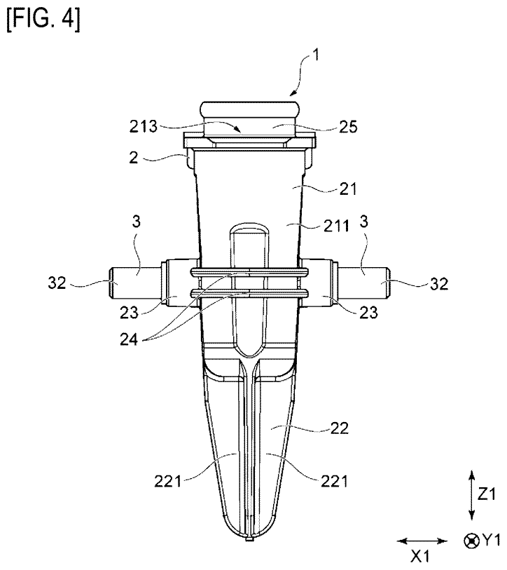

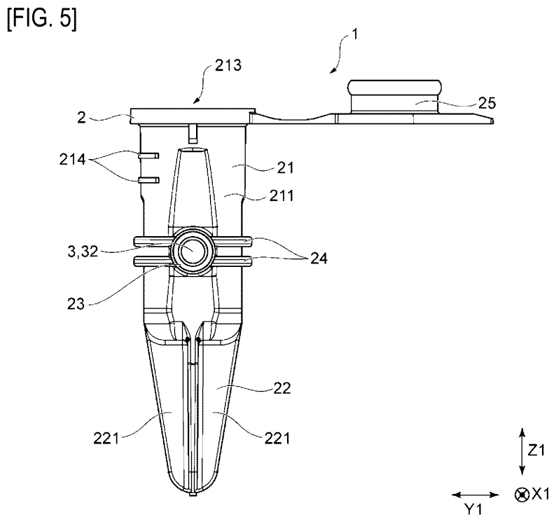

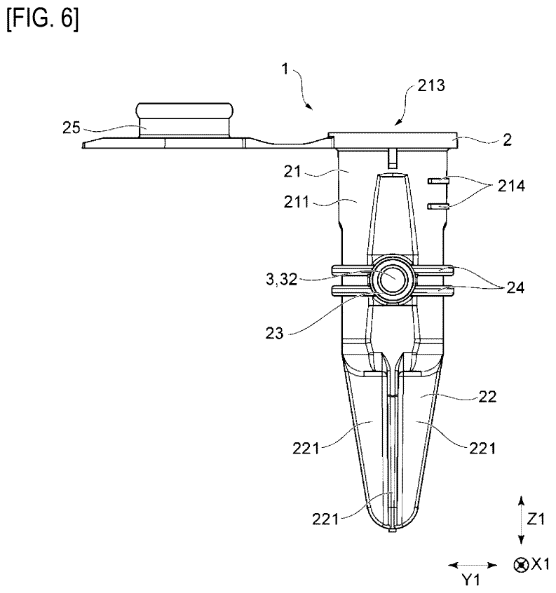

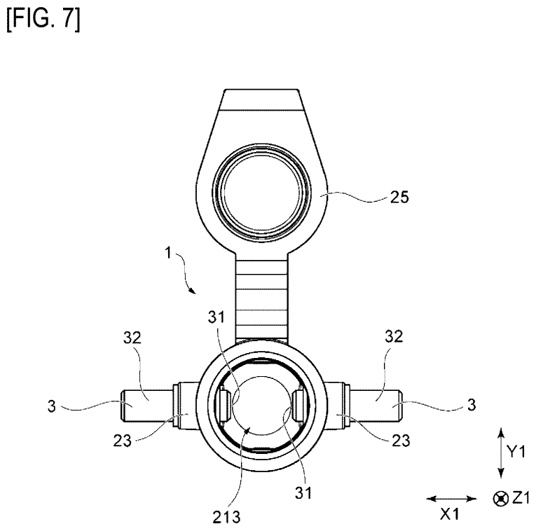

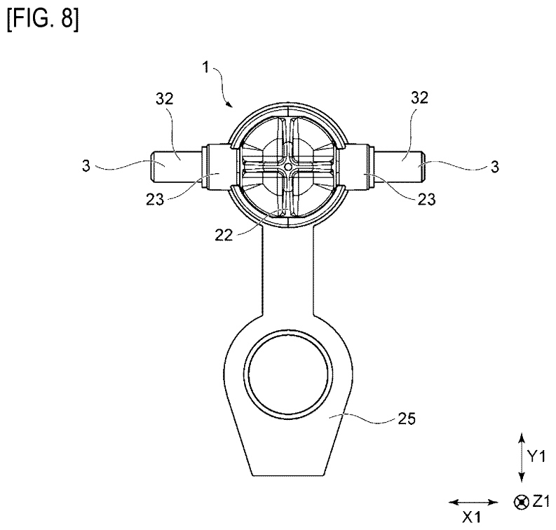

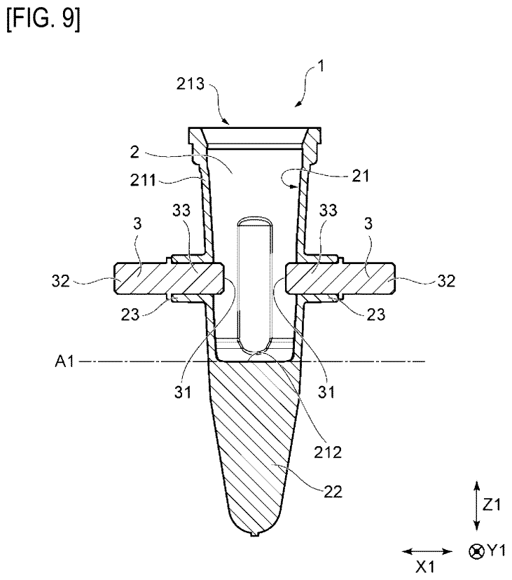

FIG. 2 is a perspective view illustrating the measurement cell 1 of the measurement unit 100 including the connection device 10 according to the embodiment, FIG. 3 is a front view illustrating the measurement cell 1, FIG. 4 is a rear view illustrating the measurement cell 1, FIG. 5 is a right side view illustrating the measurement cell 1, FIG. 6 is a left side view illustrating the measurement cell 1, FIG. 7 is a plan view illustrating the measurement cell 1, FIG. 8 is a bottom view illustrating the measurement cell 1, and FIG. 9 is a cross-sectional view illustrating the measurement cell 1.

The measurement cell 1 is a cell for measuring the impedance of the slurry, and includes a containing portion for containing the slurry (referred to as a slurry containing portion 2 in the present embodiment) and a pair of electrode portions 3 attached to the slurry containing portion 2.

The slurry containing portion 2 is made of a translucent resin (a translucent member), such as polypropylene or the like. Note that the material of the slurry containing portion 2 may be any material as long as it is suitable for the type, temperature, and the like of the liquid to be contained. For example, in the case of containing a highly reactive liquid, a fluororesin may be used. The slurry containing portion 2 is formed in a cylindrical shape extending along a predetermined direction as a whole, and hereinafter, the predetermined direction is referred to as a Z1 direction, and two directions orthogonal to the Z1 direction and orthogonal to each other are referred to as a X1 direction and a Y1 direction. The measurement cell 1 is used such that the Z1 direction substantially coincides with the vertical direction. One side in the Z1 direction may be simply referred to as an upper side, and the other side may be simply referred to as a lower side.

The slurry containing portion 2 integrally includes a tube-like portion 21, a protruding portion 22, a pair of tubular attachment portions 23, a reinforcing portion 24, and a lid portion 25.

The tube-like portion 21 includes a tube-like portion main body 211 extending along the Z1 direction and a bottom portion 212 provided at a lower end (the other end) of the tube-like portion main body 211 and is formed in a bottomed tubular shape with an upper end (one end) opening. In other words, the tube-like portion 21 includes an opening portion 213 at the upper end thereof, and the opening portion 213 side is an inlet side.

In the tube-like portion main body 211, a reference line 214 is formed on the upper side from the tubular attachment portions 23 and the reinforcing portion 24 (closer to the inlet side than inner electrodes 31 to be described later). A form of the reference line 214 is not particularly limited, and the reference line 214 may be formed on either the inner surface or the outer surface of the tube-like portion main body 211, and may be formed in a concave shape or a convex shape, for example. In the present embodiment, the reference line 214 extends along the circumferential direction centering around the Z1 direction, and two of these reference lines 214 are formed so as to be aligned in the Z1 direction. When a liquid level is positioned between the two reference lines 214, an appropriate amount of slurry is contained. The two reference lines 214 are both positioned on the upper side from the tubular attachment portions 23, and in particular, the lower reference line 214 is preferably positioned on the upper side from the tubular attachment portions 23 by 1 mm or more.

Note that, in the illustrated example, the tube-like portion main body 211 has the cylindrical shape having a substantially constant inner diameter and outer diameter, but the tube-like portion main body 211 may have a cylindrical shape extending with a slight inclination with respect to the Z1 direction (a cylinder having a truncated conical cross section), and the inner and outer diameters may become smaller toward the lower side.

The protruding portion 22 is a portion that is continuous with the lower end of the tube-like portion 21, has an outer diameter that decreases toward the tip end (the lower end), and is inserted into a holder having a plurality of openings in an upper surface thereof. That is, a plurality of the measurement cells 1 can be inserted into such a holder. The protruding portion 22 includes four triangular plate-shaped portions 221, and these plate-shaped portions 221 share a side extending along the Z1 direction, an upper side is shared with the bottom portion 212, and an outer diameter of a virtual conical shape obtained by connecting hypotenuses of these sides is referred to as an outer diameter of the protruding portion 22. Note that the protruding portion may have a shape in which the outer diameter decreases toward the tip end, and may have a conical or truncated conical side surface.

The bottom portion 212 of the tube-like portion 21 is disposed at substantially the same height as a boundary portion A1 between the tube-like portion 21 and the protruding portion 22 in the Z1 direction (see FIG. 9). That is, the slurry contained in the tube-like portion 21 is not contained in the protruding portion 22. The bottom portion 212 includes the boundary portion A1, is disposed on the upper side (one end side), and may be disposed at substantially the same height as the boundary portion A1 as described above or on the upper side from the boundary portion A1.

The tubular attachment portions 23 protrude outward from the tube-like portion main body 211 of the tube-like portion 21, the electrode portion 3 being inserted through the tubular attachment portions 23. The tubular attachment portion 23 is formed in a circular cylindrical shape extending along the X1 direction. The shape of the tubular attachment portion 23 may be any shape as long as it corresponds to the shape of the electrode portion 3. For example, in a case where the electrode portion has a square columnar shape, the tubular attachment portion may also have a square tubular shape. Note that, in the illustrated example, the tubular attachment portion 23 only protrudes to the outer side from the tube-like portion main body 211, but may protrude both to the inner side and the outer side, or may only protrude to the inner side.

The reinforcing portion 24 is a rib extending between the pair of tubular attachment portions 23. In other words, the reinforcing portion 24 is formed in an arc shape extending along the circumferential direction centering around the Z1 direction. In the illustrated example, the reinforcing portion 24 is composed of two ribs, but the number of ribs is not limited thereto, and may be one or may be three or more.

The lid portion 25 is for closing the opening portion 213 of the tube-like portion 21. That is, by bending a flexible portion connecting the lid portion 25 and the tube-like portion 21, the opening portion 213 can be closed by the lid portion 25. The flexible portion need not necessarily be provided, and the lid portion may be configured as a separate component from the tube-like portion.

The electrode portion 3 is made of a conductive metal and has a cylindrical shape extending in the X1 direction. Of portions of the electrodes 3 positioned inside the slurry containing portion 2, end surfaces serve as inner electrodes 31. Of portions of the electrodes 3 positioned outside the slurry containing portion 2, end surfaces serve as outer electrodes 32. Portions of the electrodes 3 positioned inside the tube-like portion 21 serve as connection portions 33 connecting the inner electrodes 31 and the outer electrodes 32. It is preferable that the inside of the electrode portion 3 is also filled with a metal member, but the inside may be hollow. The outer diameter of the electrode portion 3 is slightly larger than the inner diameter of the tubular attachment portion 23 in a state before attachment, and the electrode portion 3 is attached to the slurry containing portion 2 by being press-fitted thereto. Note that the electrode portion 3 may be formed integrally with the slurry containing portion 2.

The inner electrodes 31, which are the end surfaces of the electrode portions 3, extend along a Y1Z1 plane, and the inner electrodes 31 of the pair of electrode portions 3 function as parallel flat plates disposed to face each other at a predetermined interval in the X1 direction. In the illustrated example, the inner electrode 31 has a circular shape, but the shape is not limited thereto and may be a polygonal shape. The inner electrode that is the end surface need not necessarily have a planar shape but may have a curved shape such as a hemispherical shape.

The outer electrode 32 includes a tube-like portion an end surface exposed from the tubular attachment portion 23 and can be electrically connected to a mating terminal or the like when contacting the mating terminal at any position.

### [Connection Device]

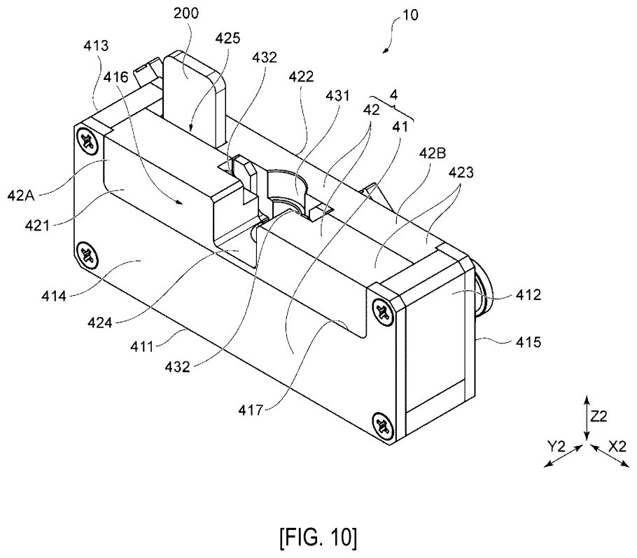

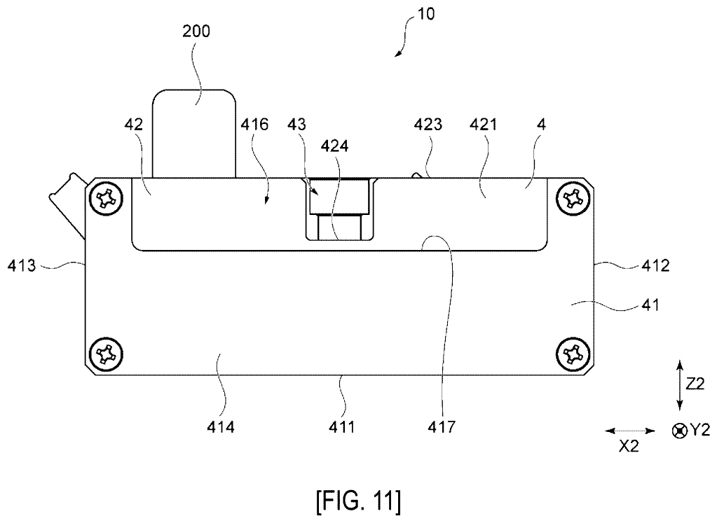

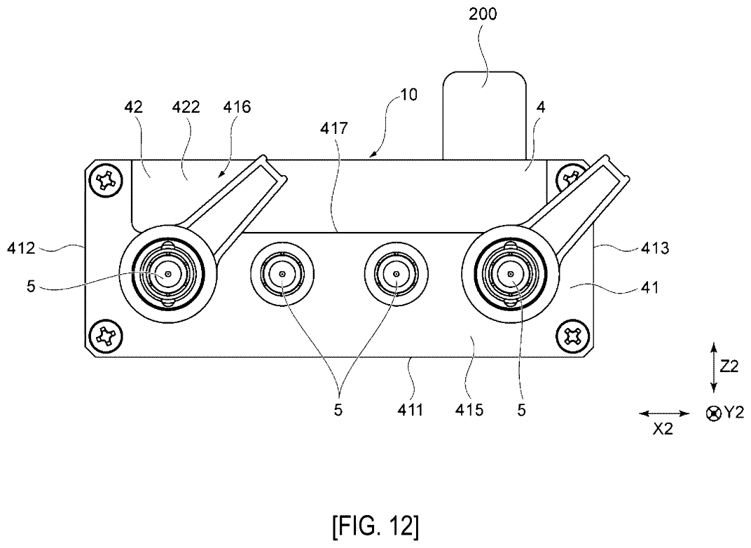

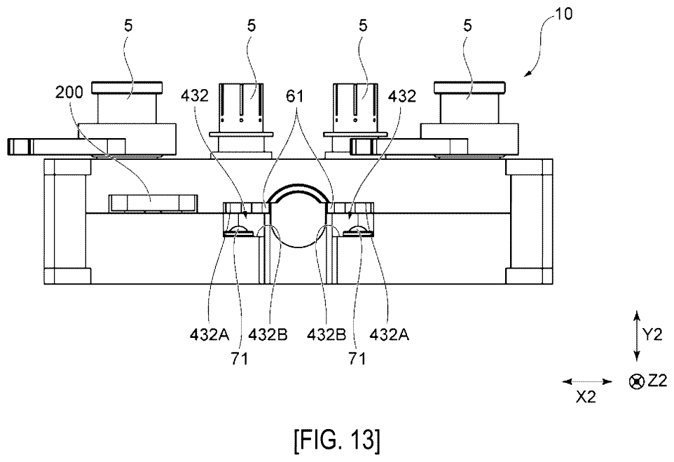

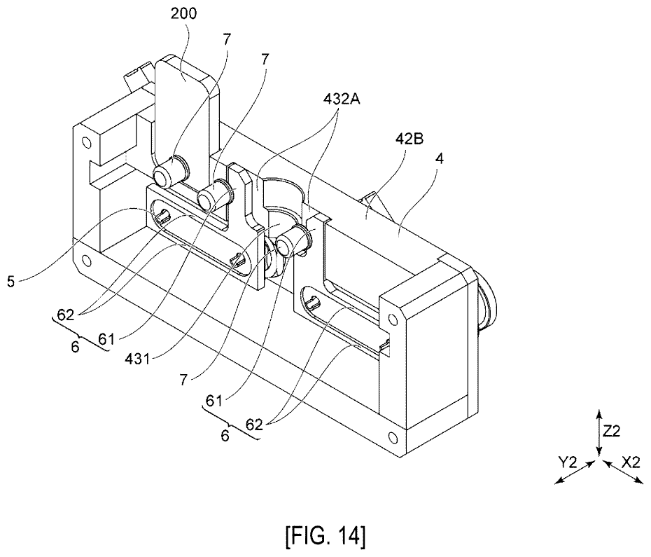

FIG. 10 is a perspective view illustrating the connection device 10 according to the embodiment, FIG. 11 is a front view illustrating the connection device 10, FIG. 12 is a rear view illustrating the connection device 10, FIG. 13 is a plan view illustrating the connection device 10, and FIG. 14 is a perspective view illustrating a part of the connection device 10.

The connection device 10 is used together with the above-described measurement cell 1 for measuring the impedance of the slurry, and includes a casing portion 4, a terminal portion 5, and a pair of electrode members 6.

The casing portion 4 is formed in a rectangular parallelepiped shape as a whole. Hereinafter, a height direction of the casing portion 4 is referred to as a Z2 direction, a long-side direction thereof is referred to as a X2 direction, and a short-side direction thereof is referred to as a Y2 direction. The connection device 10 is used such that the Z2 direction substantially coincides with the vertical direction. One side in the Z2 direction may be simply referred to as the upper side and the other side may be simply referred to as the lower side.

The casing portion 4 includes a shield portion 41 that mainly constitutes an outer shell of the casing portion 4, and an insulator portion 42 that is provided on an upper surface of the casing portion 4.

The shield portion 41 is formed in a box shape integrally including a bottom surface portion 411, side surface portions 412 and 413 provided on both sides in the X2 direction, and side surface portions 414 and 415 provided on both sides in the Y2 direction, and has an opening portion 416 on the upper side. The box-shaped shield portion 41 is formed in a hollow shape. The bottom surface portion 411 constitutes a bottom surface portion of the casing portion 4, the side surface portions 412 and 413 constitute side surface portions of the casing portion 4, and the side surface portions 414 and 415 constitute most of side surface portions of the casing portion 4. The shield portion 41 is made of a conductive metal member, and is preferably made of a material that can reduce noise during the impedance measurement. Each of the portions constituting the shield portion 41 may be made of a plate-like member, which may be fixed to each other by screws, for example.

Cutout portions 417 are formed in the upper sides (end edges on the opening portion 416 side) of the side surface portions 414 and 415. The cutout portion 417 is U-shaped when viewed from the Y2 direction.

The insulator portion 42 is made of an insulator such as resin, and is housed in the opening portion 416 of the shield portion 41. The insulator portion 42 includes side surface portions 421 and 422 provided on both sides in the Y2 direction, and an upper surface portion 423 constituting most of the upper surface portion of the casing portion 4. The side surface portions 421 and 422 are disposed in the cutout portions 417 without a gap, and are disposed in the same plane as the side surface portions 414 and 415, thus constituting the side surface portions of the casing portion 4 as a whole. The insulator portion 42 is divided into two parts in the Y2 direction, and a first component 42A and a second component 42B are assembled.

A housing recess (referred to as a measurement cell housing recess 43 in the present embodiment), which opens upward and houses the measurement cell 1 that includes the slurry containing portion 2 that is the cylindrical portion, is formed in the insulator portion 42. When the measurement cell 1 is housed in the measurement cell housing recess 43 in a normal posture, the X1 direction and the X2 direction coincide with each other, the Y1 direction and the Y2 direction coincide with each other, and the Z1 direction and the Z2 direction coincide with each other. The measurement cell housing recess 43 includes a cylindrical measurement cell main casing portion 431 that houses the tube-like portion 21 and the protruding portion 22 of the measurement cell 1, and a measurement cell sub-housing portion 432 that houses the pair of tubular attachment portions 23.

The measurement cell main housing portion 431 includes a portion having an inner diameter substantially equal to an outer diameter of a predetermined portion of the tube-like portion 21 or the protruding portion 22. Accordingly, when the measurement cell 1 is housed in the measurement cell housing recess 43, the tube-like portion 21 or the protruding portion 22 comes into contact with the inner surface of the measurement cell main housing portion 431, and downward movement of the measurement cell 1 is restricted. In this way, the measurement cell 1 is housed to a predetermined housing depth in the measurement cell housing recess 43.

The measurement cell sub-housing portion 432 is a groove portion that is continuous with the measurement cell main housing portion 431 and extends toward both sides in the X2 direction. The measurement cell sub-housing portion 432 has a bottom surface portion, but the bottom surface portion may be omitted. Instead of the configuration in which the tube-like portion 21 or the protruding portion 22 abuts against the inner surface of the measurement cell main housing portion 431 as described above, the tubular attachment portion 23 or the electrode portions 3 of the measurement cell 1 may abut against the bottom surface portion of the measurement cell sub-housing portion 432 to restrict insertion in the Z2 direction.

A groove portion 424 that is continuous with the measurement cell main housing portion 431 and extends in the Y2 direction is formed in the first component 42A, of the insulation portion 42, that is positioned on the front side in FIG. 10. The groove portion 424 is formed extending to both end portions of the first component 42A in the Y2 direction, and the measurement cell 1 housed in the measurement cell main housing portion 431 can be visually recognized from the Y2 direction.

A recess 425 for housing an electrode plate 200 is formed in the second component 42B positioned on the front side in FIG. 10 of the insulation portions 42, at a boundary portion with the first component 42A, in the upper surface portion 423. The electrode plate 200 is disposed in the measurement cell housing recess 43 in order to short-circuit a pair of contact portions 61, and is used for blank measurement. Pressing portions 7 to be described later are provided in the recess 425, so that the housed electrode plate 200 is pressed.

The terminal portion 5 is connected to a measuring device for measuring the electrical characteristics of the liquid contained in the measurement cell 1, and may be a connector of an appropriate mode, such as a BNC connector, for example, and the shape and dimensions of the connector may be those corresponding to the type of the measuring device, the cable to be used, and the like. In the present embodiment, four of the terminal portions 5 for two-terminal method measurement are aligned in the X2 direction, and the two terminal portions 5 at both ends have a locking mechanism for locking with a mating connector. However, the configuration is not limited to such a mode, and the locking mechanism may be provided at any appropriate position, or the locking mechanism need not necessarily be provided.

The electrode members 6 are respectively in contact with the pair of electrode portions 3 provided in the measurement cell 1, are formed in an L-shape by a metal plate, extend along a Z2X2 plane, and are housed in the casing portion 4. Portions, of the L-shaped electrode members 6, extending in the Z2 direction and housed in the measurement cell sub-housing portion 432 serve as the contact portions 61 that come into contact with the outer electrodes 32 of the electrode portions 3 of the measurement cell 1, and portions extending in the X2 direction serve as connection portions 62 that electrically connect the terminal portions 5 and the contact portions 61.

The contact portions 61 are provided along one surface (a surface of the second component 42B) 432A, of a pair of inner surfaces facing each other in the Y2 direction in the groove-shaped measurement cell sub-housing portion 432. The pressing portions 7 are provided on the other surface (a surface of the first component 42A) 432B of the pair of inner surfaces, so as to face the contact portions 61. Note that, in FIG. 14, the first component 42A is omitted and the pressing portions 7 are illustrated.

The pressing portion 7 includes a ball 71 and an urging member, such as a spring, that presses the ball 71 toward the one surface 432A. The ball 71 and the contact portion 61 are disposed at a predetermined interval in the Y2 direction, and the outer electrode 32 of the electrode portion 3 of the measurement cell 1 is disposed in this gap. The gap is slightly smaller than the outer diameter (the dimension in the Y2 direction) of the outer electrode 32. When the electrode portion 3 is inserted into the gap by moving in the Z2 direction, the outer electrode 32 comes into contact with the ball 71 to compress the urging member, thus generating a restoring force. When the measurement cell 1 is inserted to a predetermined depth, the maximum outer diameter portion of the outer electrode 32 is positioned on the lower side from the ball 71, and the urging member is restored from a maximum compressed state. Thus, in a state in which the measurement cell 1 is inserted to the predetermined depth, the outer peripheral surface of the outer electrode 32 is pressed against the contact portion 61 by the restoring force of the urging member, and the electrode portion 3 is suppressed from moving to the upper side.

The connection portion 62 is housed on the lower side of the insulator portion 42, and is configured to branch the one contact portion 61 into two portions to be connected to two of the terminal portions 5.

In the connection device 10 as described above, the shield portion 41 includes the side surface portions 412 and 413 as a pair of opposing plate portions at positions at which the pair of contact portions 61 are sandwiched from the X2 direction that is an opposing direction in which the pair of contact portions 61 face each other. Furthermore, the shield portion 41 includes the side surface portions 414 and 415 as a pair of connecting plate portions that connect the pair of opposing plate portions (the side surface portions 412 and 413). At the end edge of the opening portion 416 side (the upper side) of each of the side surface portions 414 and 415, the cutout portion 417 is formed at the position at which the contact portions 61 are sandwiched. At this time, in the Z2 direction, the depth of the cutout portion 417 is larger than the depth of the measurement cell sub-housing portion 432, and a contact position between the outer electrode 32 and the contact portion 61 is positioned above the bottom edge of the cutout portion 417.

### [Measurement Unit]

The relationship between the measurement cell 1 and the connection device 10 in the measurement unit 100 as a whole will be described. The positional relationship of each of portions in the following description is assumed to be a positional relationship in a state in which the measurement cell 1 is housed to the predetermined housing depth in the measurement cell housing recess 43.

As a result of the measurement cell 1 moving in the Z2 direction with respect to the connection device 10, mainly the protruding portion 22 is inserted into the measurement cell main housing portion 431 of the measurement cell housing recess 43. At this time, the urging member of the pressing portion 7 is compressed and restored, as described above. When the measurement cell 1 is housed to the predetermined housing depth in the measurement cell housing recess 43, the tube-like portion 21 or the protruding portion 22 comes into contact with the inner surface of the measurement cell main housing portion 431, and the downward movement of the measurement cell 1 is restricted. In this state, the outer electrode 32 and the contact portion 61 come into contact with each other and are electrically connected to each other.

Furthermore, by connecting a terminal extending from the measurement device to the terminal portion 5, the impedance of the slurry contained in the measurement cell 1 can be measured. Note that the measurement device and the terminal portion 5 may be always electrically connected to each other and the measurement cell 1 may be replaced, and this order is not limited.

In the state in which the measurement cell 1 is housed to the predetermined housing depth in the measurement cell housing recess 43, the casing portion 4 preferably includes a tilt restriction portion that can come into contact with, from the Y2 direction, a portion of the measurement cell 1 on the upper side from the portion housed in the measurement cell housing recess 43. Such a tilt restriction portion can suppress tilting of the measurement cell 1 when viewed from the X2 direction. Note that a position, of the measurement cell 1, at which the tilt restriction portion comes into contact may be the slurry containing portion 2 or the electrode portion 3.

According to the present embodiment, since the measurement cell 1 includes the pair of electrode portions 3 attached to the slurry containing portion 2, the interval and the positional relationship between the pair of inner electrodes 31 can be easily kept constant, and the measurement accuracy of the electrical characteristics of the liquid can be improved.

The slurry containing portion 2 includes the protruding portion 22 whose outer diameter decreases toward the tip end, thus allowing the slurry containing portion 2 to be easily held by the holder. It is only required that the holder be able to hold, by including, for example, a plurality of recesses, the measurement cell 1 in each of the recesses and hold a plurality of the measurement cells 1. At this time, the tube-like portion 21 of the slurry containing portion 2 includes the boundary portion A1 and the bottom portion 212 at a position on the upper side, thus causing the slurry not to be stored in the protruding portion 22. For this reason, compared to a configuration in which the slurry is contained in a portion whose inner diameter decreases toward the tip end, it is possible to suppress mixing of air bubbles into the liquid, and thus improve the measurement accuracy of the electrical characteristics.

The electrode portion 3 is a rod-shaped member penetrating the slurry containing portion 2, allowing for making attachment operation to the slurry containing portion 2 easy. Further, since the slurry containing portion 2 includes the tubular attachment portion 23, it is possible to suppress inclination of the attached rod-shaped electrode portion 3 and to make it less likely for the relative position or the like of the pair of inner electrodes 31 to change, thus making it possible to improve the measurement accuracy of the electrical characteristics.

Furthermore, since the slurry containing portion 2 includes the reinforcing portion 24 extending between the pair of tubular attachment portions 23, it is possible to suppress deformation of the slurry containing portion 2 is suppressed, particularly to suppress deformation in which the electrode portions 3 move in the Z1 direction, making it less likely for the relative position or the like of the pair of inner electrodes 31 to change, thus making it possible to improve the measurement accuracy of the electrical characteristics.

The slurry containing portion 2 is made of the translucent member, the reference lines 214 are formed closer to the inlet side than the inner electrode 31, and thus the entire inner electrode 31 can be immersed in the liquid. In other words, it is possible to suppress the inner electrode 31 from being exposed from the liquid and thus improve the measurement accuracy of the electrical characteristics.

In the connection device 10, since the contact portion 61 is disposed at a position at which the contact portion 61 comes into contact with the outer electrode 32 when the measurement cell 1 is housed to the predetermined housing depth in the measurement cell accommodation recess 43, the electrode portion 3 for measuring the electrical characteristics of the liquid and the measurement device can be easily connected to each other. When the electrical characteristics of a liquid object are measured using the four-terminal measurement method or the like, it is necessary to dispose the pair of counter electrodes in the liquid contained in the cell or the like and to connect these counter electrodes to the measurement device, and it is difficult to bring the contact terminal described in Patent Document 1 into contact with this type of the counter electrodes. According to the present embodiment, the electrode portion 3 for measuring the electrical characteristics of the liquid is more easily connected to the measurement device than when using a method for connecting a measurement electric wire to the counter electrode using an alligator clip or the like, for example.

The casing portion 4 includes the shield portion 41 made of metal at the positions at which the pair of contact portions 61 are sandwiched from the X2 direction that is the opposing direction, allowing for reducing noise in measuring the electrical characteristics of the liquid.

Furthermore, since at the end edge on the opening portion 416 side of each of the side surface portions 414 and 415 that are the connection plate portions, the cutout portion 417 is formed at the position at which the contact portions 61 are sandwiched, it is possible to suppress the contact portions 61 and metal members from being disposed close to each other, and is thus possible to reduce parasitic capacitance generated between the liquid and the metal members when measuring the electrical characteristics of the liquid.

### Extension of Embodiment

Although the invention by the inventors of the present application has been specifically described based on the embodiment, the present invention is not limited to the embodiment, and it is needless to say that various changes can be made insofar as they do not depart from the scope and gist of the present invention.

For example, in the above-described embodiment, the tube-like portion 21 of the slurry containing portion 2 includes the boundary portion A1 and the bottom portion 212 at a position on the upper side, but the configuration is not limited to such a configuration. That is, the containing portion may have a portion housed in the holder as a result of reducing the outer diameter toward the tip end portion, and the liquid may be contained inside this portion. In this case, for example, the inner diameter of the tip end portion may be formed to be sufficiently large, or a surface treatment may be performed, so that air bubbles are not likely to be generated. The portion housed in the holder may have a substantially constant outer diameter and inner diameter, and the liquid may be contained inside this portion.

In the above-described embodiment, the slurry containing portion 2 includes the reinforcing portion 24 extending between the pair of tubular attachment portions 23. However, when the containing portion is less likely to be deformed as a result of being made of a relatively hard material or having a sufficiently large thickness, for example, the reinforcing portion may be omitted. Appropriate reinforcing portions may be provided at other positions.

In the above-described embodiment, the slurry containing portion 2 includes the tubular attachment portions 23, but when inclination of the electrode portion is less likely to occur due to the thickness of the containing portion being sufficiently thick, due to another fixing member being provided or the like, for example, the tubular attachment portions may be omitted.

In addition, in the above-described embodiment, the electrode portion 3 is a rod-like member penetrating the slurry containing portion 2, but the electrode unit is not limited to a rod-like shape and may not penetrate the containing portion. For example, the electrode unit may be configured to have a plate-shaped inner electrode and outer electrode, and a connection portion that connects the inner electrode and the outer electrode at the opening of the containing portion (that is, to have a U-shaped cross-section).

In the above-described embodiment, the slurry containing portion 2 is formed of the translucent member, and the reference lines 214 are formed closer to the inlet side than the inner electrodes 31. However, a sufficient liquid level may be secured by another method. For example, in a case in which a relationship between the liquid level and the inner electrode is visible when viewing the containing portion from the opening side, or in a case in which the amount of the liquid to be contained is controlled, or the like, it is possible to secure the sufficient liquid level for measurement. In such a case, the containing portion may be opaque, or the reference line need not necessarily be formed.

In the above-described embodiment, the cutout portions 417 are formed in the side surface portions 414 and 415. However, in a case in which the size of the shield portion is large and the parasitic capacitance generated between the liquid and the metal member is small, the cutout portions need not necessarily be formed.

In the above-described embodiment, the casing portion 4 includes the shield portion 41. However, in a case in which each of the devices is used in an environment in which noise is less likely to occur at the time of measurement, or in a case in which the electrical identification to be measured is less likely to be affected by noise, the shield portion need not necessarily be provided.

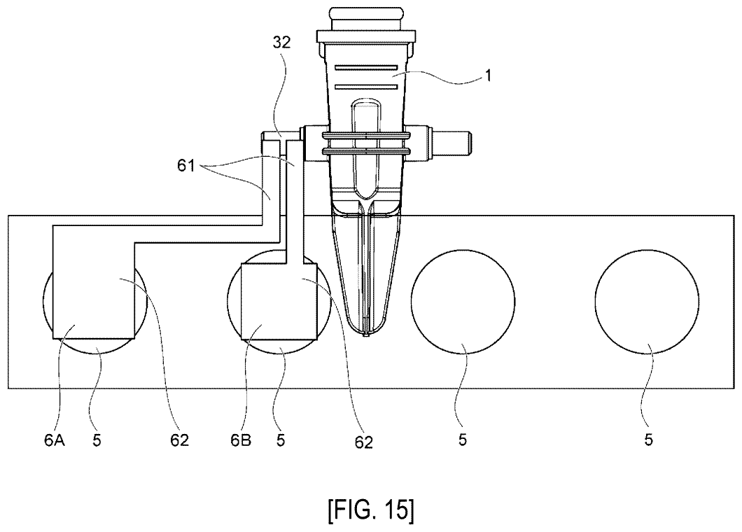

Although the impedance is measured by the two-terminal method in the above-described embodiment, the electrical characteristics may be measured by another appropriate method. For example, as schematically illustrated in FIG. 15, the four-terminal method may be employed. In this mode, two types of electrode portions 6A and 6B each include the contact portion 61 so as to be in contact with the outer electrodes 32 at mutually different positions. Two electrode members on the right side, which are not illustrated in FIG. 15, have a shape symmetrical to that on the left side.

Although the embodiments of the present invention have been described in detail with reference to the drawings, specific configurations are not limited to these embodiments, and design changes and the like within a range not departing from the scope and gist of the present invention are also included in the present invention.

### REFERENCE SIGNS LIST

1. Measurement cell, 2. Slurry containing portion (containing portion), 21. Tube-like portion, 212. Bottom portion, 214. Reference line, 22. Protruding portion, 23. Tubular attachment portion, 3. Electrode portion, 31. Inner electrode, 32. Outer electrode, 10. Connection device, 4. Casing portion, 41. Shield portion, 412, 413. Side surface portion (opposing plate portion), 414, 415. Side surface portion (connection plate portion), 416. Opening portion, 417. Cutout portion, 42. Insulator portion, 43. Measurement cell housing recess (housing recess), 5. Terminal portion, 61. Contact portion, 62. Connection portion.

1. A measurement cell for measuring electrical characteristics of a liquid, the measurement cell comprising:
a containing portion configured to contain a liquid; and
a pair of electrode portions attached to the containing portion,
wherein the pair of electrode portions each include an inner electrode provided inside the containing portion and an outer electrode provided outside the containing portion, the inner electrodes of the pair of electrode portions facing each other.

2. The measurement cell according to claim 1, wherein the containing portion includes:
a tube-like portion whose one end opens, and
a protruding portion that is continuous with the other end of the tube-like portion and has an outer diameter decreasing toward a tip end, and
the tube-like portion includes a boundary portion with the protruding portion, includes a bottom portion at a position on a side of the one end, and is capable of containing the liquid.

3. The measurement cell according to claim 1, wherein the electrode portion is a rod-shaped member penetrating the containing portion.

4. The measurement cell according to claim 3, wherein the containing portion includes a tubular attachment portion that protrudes outward, the electrode portion being inserted through the tubular attachment portion.

5. The measurement cell according to claim 4, wherein the containing portion includes a reinforcing portion extending between a pair of the tubular attachment portions.

6. The measurement cell according to claim 1, wherein the containing portion is made of a translucent member and includes a reference line closer to an inlet side than the inner electrode.

7. A connection device, comprising:
a housing recess configured to house a measurement cell including a tube-like portion;
a terminal portion to be connected to a measurement device for measuring electrical characteristics of a liquid contained in the measurement cell;
a pair of contact portions configured to contact a pair of respective electrode portions provided in the measurement cell; and
a connection portion configured to electrically connect the terminal portion and the contact portion,
wherein the contact portions are disposed at positions contacting the respective electrode portions when the measurement cell is housed to a predetermined housing depth in the housing recess.

8. The connection device according to claim 7, comprising.
a casing portion in which the housing recess is formed,
wherein the casing portion includes a metal shield portion at least at positions at which the pair of contact portions are sandwiched from an opposing direction in which the pair of contact portions face each other.

9. The connection device according to claim 8,
wherein the casing portion includes an insulator portion in which the housing recess is formed,
the shield portion is formed in a box shape and includes an opening portion in which the insulator portion is housed, a pair of opposing plate portions facing each other in the opposing direction, and a pair of connection plate portions connecting the pair of opposing plate portions to each other, and
at an end edge on a side of the opening portion of each of the pair of connection plate portions, a cutout portion is formed at a position at which the contact portions are sandwiched.
